(19) United States
(12) Patent Application Publication
(10) Pub. No.: US 2025/0338495 A1
(43) Pub. Date: Oct. 30, 2025

(54) SEMICONDUCTOR DEVICE

(71) Applicant: Samsung Electronics Co., Ltd., Suwon-si (KR)

(72) Inventors: Hanhyeong Choi, Suwon-si (KR); Kyongsik Yeom, Suwon-si (KR); Jongsung Woo, Suwon-si (KR); Donghwi Hwang, Suwon-si (KR)

(21) Appl. No.: 19/053,709

(22) Filed: Feb. 14, 2025

(30) Foreign Application Priority Data
Apr. 24, 2024 (KR) 10-2024-0054610

(51) Int. Cl. H10B 41/35; H10B 41/41; H10B 41/42

(52) U.S. Cl. CPC H10B 41/35; H10B 41/41; H10B 41/42

(57) ABSTRACT

A semiconductor device may include a first gate structure and a second cell gate structure on a cell region of a substrate, an erase gate structure on the substrate between respective first sidewalls of the first cell gate structure and the second cell gate structure, selection gate structures on the substrate that are spaced apart from respective second sidewalls facing the respective first sidewall of each of the cell gate structures, a P-type gate structure and an N-type gate structure. Each of the selection gate structures and the P-type gate structure may include a first gate insulation layer pattern including a first metal oxide and a first gate electrode pattern structure stacked on the first gate insulation layer pattern. The N-type gate structure may include the first gate insulation layer pattern including the first metal oxide and a second gate electrode pattern structure on the first gate insulation layer pattern.

### CROSS-REFERENCE TO RELATED APPLICATION

This application claims priority under 35 USC § 119 to Korean Patent Application No. 10-2024-0054610, filed on Apr. 24, 2024, in the Korean Intellectual Property Office (KIPO), the contents of which are incorporated by reference herein in their entirety.

### BACKGROUND

Various example embodiments relate to a semiconductor device. Particularly, various example embodiments relate to a semiconductor device including non-volatile memory cells and peripheral circuits.

As a degree of integration of semiconductor devices increases, it is not easy to form transistors having target characteristics in the semiconductor device. Additionally, it is not easy to manufacture various transistors having different characteristics in the semiconductor device by simple processes.

### SUMMARY

Various example embodiments provide a semiconductor device including transistors having target characteristics.

According to some example embodiments, there is provided a semiconductor device. The semiconductor device may include a first cell gate structure and a second cell gate structure on a cell region of a substrate, an erase gate structure on the substrate between respective first sidewalls of the first cell gate structure and the second cell gate structure, selection gate structures on the substrate that are spaced apart from respective second sidewalls facing the respective first sidewalls of each of the first cell gate structure and the second cell gate structure, a P-type gate structure on a peripheral circuit region of the substrate, and an N-type gate structure on the peripheral circuit region of the substrate. Each of the selection gate structures may include a first gate insulation layer pattern that includes a first metal oxide and a first gate electrode pattern structure on the first gate insulation layer pattern. The P-type gate structure may include the first gate insulation layer pattern that includes the first metal oxide and the first gate electrode pattern structure on the first gate insulation layer pattern. The N-type gate structure may include the first gate insulation layer pattern including the first metal oxide and a second gate electrode pattern structure on the first gate insulation layer pattern. The second gate electrode pattern structure may have a stacked structure different from a stacked structure of the first gate electrode pattern structure.

According to some example embodiments, there is provided a semiconductor device. The semiconductor device may include a first cell transistor and a second cell transistor on a cell region of a substrate, an erase transistor between the first cell transistor and the second cell transistor, selection transistors on the substrate that are spaced apart from the cell transistors, a P-type transistor on a peripheral circuit region of the substrate, and an N-type transistor on the peripheral circuit region of the substrate. Each of the selection transistors may have a selection gate structure including an interface layer, a first gate insulation layer pattern including a first metal oxide having a dielectric constant higher than a dielectric constant of silicon nitride, and a first gate electrode pattern structure on the first gate insulation layer pattern and having a first stacked structure. The P-type transistor may have the interface layer, the first gate insulation layer pattern including the first metal oxide, and the first gate electrode pattern structure on the first gate insulation layer pattern and having the first stacked structure. The N-type transistor may have the interface layer, the first gate insulation layer pattern including the first metal oxide, and a second gate electrode pattern structure on the first gate insulation layer pattern and having a second stacked structure different from the first stacked structure.

According to some example embodiments, there is provided a semiconductor device. The semiconductor device may include a selection gate structure on a cell region of a substrate, a P-type gate structure on a peripheral circuit region of the substrate, an N-type gate structure on the peripheral circuit region of the substrate, first source/drain regions doped with N-type impurities at the substrate adjacent to sidewalls of the selection gate structure, second source/drain regions doped with P-type impurities on the substrate adjacent to sidewalls of the P-type gate structure, and third source/drain regions doped with N-type impurities on the substrate adjacent to sidewalls of the N-type gate structure. The selection gate structure may include a first gate electrode pattern structure and a second gate electrode pattern structure on the first gate electrode pattern structure. The first gate electrode pattern structure may include an interface layer, a first gate insulation layer pattern including a first metal oxide, a first conductive layer pattern on the first gate insulation layer pattern, a first work function control layer pattern and a second conductive layer pattern. The second gate electrode pattern structure may include a second work function control layer pattern and a third conductive layer pattern. The P-type gate structure may include the first gate electrode pattern structure and the second gate electrode pattern structure on the first gate electrode pattern structure. The N-type gate structure may include the interface layer, the first gate insulation layer pattern including the first metal oxide, and the second gate electrode pattern structure on the first gate insulation layer pattern.

According to example embodiments, in the semiconductor device, the selection gate structure and the P-type gate structure have the same stacked structure. Thus, the selection gate structure and the P-type gate structure may be formed by a simple process. In addition, damages of the first gate insulation layer pattern included in the selection gate structure may be decreased, and thus electrical characteristics of the selection transistor including the selection gate structure may be improved. Accordingly, electrical characteristics of the semiconductor device may be improved.

### BRIEF DESCRIPTION OF THE DRAWINGS

Various example embodiments will be more clearly understood from the following detailed description taken in conjunction with the accompanying drawings. FIGS. 1 to 14 represent various non-limiting, example embodiments as described herein.

FIG. 1 is a cross-sectional view of a semiconductor device according to example embodiments; and

FIGS. 2 to 14 are cross-sectional views illustrating a method of manufacturing a semiconductor device according to example embodiments.

### DETAILED DESCRIPTION

Hereinafter, various example embodiments will be described in detail with reference to the accompanying drawings.

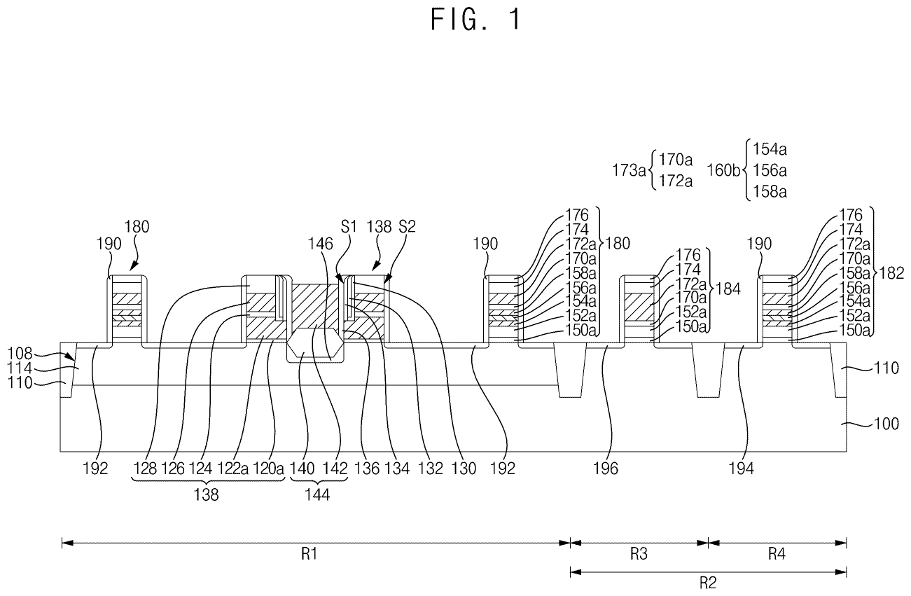

FIG. 1 is a cross-sectional view of a semiconductor device according to example embodiments.

Referring to FIG. 1, a substrate 100 may include a memory cell region R1 and a peripheral circuit region R2. The memory cell region R1 may be a region where non-volatile memory cells are formed. The peripheral circuit region R2 may be a region where peripheral circuits are formed. The peripheral circuit region R2 may include an NMOS transistor region R3 and a PMOS transistor region R4.

In example embodiments, the substrate 100 may include a semiconductor material such as silicon, germanium, silicon-germanium, or a group III-V compound such as GaP, GaAs, or GaSb. In some example embodiments, the substrate 100 may be a Silicon On Insulator (SOI) substrate or a Germanium On Insulator (GOI) substrate.

An isolation trench 108 may be formed at a field region of the substrate 100, and an isolation pattern 110 may be disposed in the isolation trench 108. The isolation pattern 110 may include an insulation material. The isolation pattern 110 may include silicon oxide and/or silicon nitride. A surface of the substrate 100 between isolation patterns 110 may be provided as an active region.

In example embodiments, the isolation pattern 110 may be disposed at an interface region between the memory cell region R1 and the peripheral circuit region R2 and at an interface region between the NMOS transistor region R3 and the PMOS transistor region R4 in the peripheral circuit region R2.

A well region 114 may be formed at the memory cell region R1 of the substrate 100. The well region 114 may be doped with P-type impurities.

A cell transistor, an erase transistor, and a selection transistor may be disposed on the memory cell region R1. Unit memory cell may include the cell transistor, the erase transistor, and the selection transistor.

In example embodiments, the cell transistor may serve as a non-volatile memory cell. The non-volatile memory cell may be flash memory cell. Data may be stored in the cell transistor. The erase transistor may erase data stored in the cell transistor. The selection transistors may serve as a switch element for selecting of cell transistors.

NMOS transistors serving as the peripheral circuits may be disposed on the NMOS transistor region R3, and PMOS transistors serving as the peripheral circuits may be disposed on the PMOS transistor region R4.

A plurality of cell transistors may be disposed on the memory cell region R1 of the substrate 100. Two cell transistors may face to each other. One erase transistor may be disposed between the two cell transistors.

That is, one erase transistor may be disposed between two flash memory cells, and the erase transistor may be a shared erase transistor commonly used in the two flash memory cells. The erase transistor may erase data stored in two cell transistors disposed on both sides of the erase transistor.

The cell transistor may include a cell gate structure 138 and impurity regions. One of the impurity regions may be shared with a first source/drain region 146 of the erase transistor, and one of the impurity regions may be shared with a second source/drain region 192 of the select transistor.

The cell gate structure 138 may have a tunnel insulation layer pattern 120a, a floating gate pattern 122a, a first dielectric layer pattern 124, a control gate pattern 126, and a first hard mask pattern 128 sequentially stacked. A plurality of cell gate structures 138 may be disposed on the memory cell region R1. The two cell gate structures 138 may face to each other.

In the two opposing cell gate structures 138, facing sidewalls of the cell gate structures 138 are referred to as first sidewalls S1, and sidewalls opposite to each of the first sidewalls S1 are referred to as second sidewalls S2. A region between the first sidewalls S1 of the two opposing cell gate structures 138 may be an erase transistor region where the erase transistor is disposed. A region outside the second sidewalls S2 of the two cell gate structures 138 may be a selection transistor region where the selection transistor is disposed.

The tunnel insulation layer pattern 120a may include, e.g., silicon oxide. The floating gate pattern 122a may include, e.g., polysilicon. The first dielectric layer pattern 124 may include, e.g., silicon oxide or silicon nitride. The control gate pattern 126 may include, e.g., polysilicon. The first hard mask pattern 128 may include, e.g., silicon nitride.

In the cell gate structure 138, a width of a lower structure in which the tunnel insulation layer pattern 120a and the floating gate pattern 122a are stacked may be greater than a width of an upper structure in which the first dielectric layer pattern 124, the control gate pattern 126, and the first hard mask pattern 128 are stacked.

In example embodiments, the first sidewall S1 of the lower structure may not be aligned to the first sidewall S1 of the upper structure in a vertical direction. The first sidewall S1 of the lower structure may protrude from the first sidewall S1 of the upper structure toward the erase transistor region.

In example embodiments, in the floating gate pattern 122a, an upper surface of a portion protruding from the first sidewall of the upper structure may be lower than an upper surface of the portion facing the upper structure. In some example embodiments, in the floating gate pattern 122a, the upper surface of the portion protruding from the first sidewall of the upper structure and the upper surface of the portion facing the upper structure may be coplanar with each other.

In example embodiments, the second sidewall S2 of the lower structure may be aligned to the second sidewall S2 of the upper structure in the vertical direction. The second sidewall S2 of the lower structure may not protrude from the second sidewall S2 of the upper structure.

A first spacer structure in which a plurality of spacers is stacked may be disposed on the first sidewall S1 of the cell gate structure 138. A second spacer structure may be disposed on the second sidewall S2 of the cell gate structure 138. The second spacer structure may have a different shape from the first spacer structure

In example embodiments, a width of the first spacer structure may be greater than a width of the second spacer structure.

In example embodiments, the first spacer structure may include first, second, third, and fourth spacers 130, 132, 134, and 136. The first, second, and third spacers 130, 132, and 134 may be disposed on the first sidewall S1 of the upper structure of the cell gate structure 138. Bottoms of the first, second, and third spacers 130, 132, and 134 may contact the upper surface of the floating gate pattern 122a (i.e., the upper surface of a protruding portion of the floating gate pattern 122a). The first and third spacers 130 and 134 may include, e.g., silicon oxide, and the second spacer 132 may include, e.g., silicon nitride. The fourth spacer 136 may be disposed on the sidewalls of the third spacers 130, the floating gate pattern 122a and the tunnel insulation layer pattern 120a.

The second spacer structure may include at least one spacer. In example embodiments, the second spacer structure may include the fourth spacer 136. The fourth spacer 136 may be disposed on second sidewalls of the upper and lower structures of the cell gate structure 138. The fourth spacer 136 may include, e.g., silicon oxide or silicon nitride.

The first source/drain region 146 may be disposed below the surface of the substrate 100 in the erase transistor region. An erase gate insulation layer 140 may be disposed on the surface of the substrate 100 in the erase transistor region. In example embodiments, the erase gate insulation layer 140 may be disposed on the first source/drain region 146. The erase gate insulation layer 140 may include, e.g., silicon oxide. The erase gate insulation layer 140 may be formed by oxidation of the substrate 100. The surface of the substrate 100 under the erase gate insulation layer 140 may be lower than the surface of the substrate 100 under the cell gate structure 138. The erase gate insulation layer 140 may have a thickness greater than a thickness of the tunnel insulation layer pattern 120a of the cell gate structure 138.

An erase gate electrode or erase gate pattern 142 may be disposed on the erase gate insulation layer 140. The erase gate insulation layer 140 and the erase gate pattern 142 may serve as an erase gate structure 144.

A selection gate structure 180 in which an interface layer pattern 150a, a first gate insulation layer pattern 152a, a first gate electrode pattern structure 160b, a second gate electrode pattern structure 173a, a first capping layer pattern 174 and a second hard mask pattern 176 are stacked may be disposed on the selection transistor region. The selection gate structure 180 may be on the substrate 100 to be spaced apart from the second sidewall S2 of the cell gate structures 138. The selection gate structure 180 may extend in one direction, and the selection gate structure 180 may serve as a word line.

The interface layer pattern 150a may include an oxide, e.g., silicon oxide. The first gate insulation layer pattern 152a may include a first metal oxide having a dielectric constant higher than a dielectric constant of silicon nitride. In example embodiments, the first gate insulation layer pattern 152a may include, e.g., hafnium oxide, zirconium oxide, aluminum oxide, etc. For example, the first gate insulation layer pattern 152a may include hafnium oxide.

The first gate electrode pattern structure 160b may have a P gate electrode structure having a first work function suitable for a P-type transistor. For example, the first gate electrode pattern structure 160b may have an effective work function of about 4.9 eV to about 5.1 eV. The first gate electrode pattern structure 160b may include a first conductive layer pattern 154a, a first work function control layer pattern 156a, a second conductive layer pattern 158a.

In example embodiments, the first gate electrode pattern structure 160b may have a sandwich structure in which the first conductive layer pattern 154a, the first work function control layer pattern 156a, and the second conductive layer pattern 158a are sequentially stacked. The first and second conductive layer patterns 154a and 158a may include, e.g., TiC, Co, TiAlC, TiAl, TaN, TaAlC, etc. For example, the first and second conductive layer patterns 154a and 158a may include the same material. The first work function control layer pattern 156a may include a chemical species for controlling a threshold voltage of the P-type transistor. The first work function control layer pattern 156a may include, e.g., aluminum. For example, the first gate electrode pattern structure 160b may have a structure in which a titanium nitride layer pattern, an aluminum pattern, and/or a titanium nitride layer pattern are sequentially stacked.

In example embodiments, the second gate electrode pattern structure 173a may have a structure in which a second work function control layer pattern 170a and a third conductive layer pattern 172a are stacked. The second gate electrode pattern structure 173a may have an N gate electrode structure having a work function suitable for an N-type transistor. For example, the second gate electrode pattern structure 173a may have an effective work function of about 4.1 eV to about 4.3 eV.

The second work function control layer pattern 170a may include a chemical species for controlling the threshold voltage of the N-type transistor. The chemical species may include lanthanide elements. The second work function control layer pattern 170a may include, e.g., lanthanum oxide (LaO). The third conductive layer pattern 172a may include a metal. The third conductive layer pattern 172a may include, e.g., TiN, TaN, TaAlC, TiC, Co, TiAl, HfTi, TiSi, TaSi, etc. For example, the third conductive layer pattern 172a may include titanium nitride.

A P-type gate structure 182 in which the interface layer pattern 150a, the first gate insulation layer pattern 152a, the first gate electrode pattern structure 160b, the second gate electrode pattern structure 173a, the first capping layer pattern 174 and the second hard mask pattern 176 are stacked may be disposed on the PMOS transistor region R4.

The P-type gate structure 182 and the selection gate structure 180 may be formed by the same processes. Thus, the interface layer pattern 150a, the first gate insulation layer pattern 152a, the first gate electrode pattern structure 160b, and the second gate electrode pattern included in the P-type gate structure 182 and the interface layer pattern 150a, the first gate insulation layer pattern 152a, the first gate electrode pattern structure 160b, and the second gate electrode pattern included in the selection gate structure 180 may have same materials, respectively. Accordingly, the P-type gate structure 182 and the selection gate structure 180 may have the same stacked structure.

The P-type gate structure 182 may include the first gate electrode pattern structure 160b suitable for the P-type transistor, and the first gate electrode pattern structure 160b may contact an upper surface of the first gate insulation layer pattern 152a. Accordingly, the P-type transistor may have a target threshold voltage.

The selection gate structure 180 may include the first gate insulation layer pattern 152a having the high dielectric constant and the first gate electrode pattern structure 160b including a metal. The first gate electrode pattern structure 160b may be suitable for a P-type transistor.

As described above, the selection gate structure 180 may have the stacked structure the same as the stacked structure of the P-type gate structure 182. The selection gate structure 180 and the P-type gate structure 182 may be formed together by the same processes. Therefore, processes for manufacturing the semiconductor device may be simplified. Additionally, in the processes for stacking of layers included in the selection gate structure, an etching process and a cleaning process of the first gate insulation layer may not be performed. Accordingly, damages of the first gate insulation layer pattern 152a may be decreased due to the etching process and the cleaning process of the first gate insulation layer, and the cell transistor may have excellent electrical characteristics. For example, a distribution of on-currents of the cell transistor and leakage currents of the cell transistor may be decreased.

A N-type gate structure 184 in which the interface layer pattern 150a, the first gate insulation layer pattern 152a, the second gate electrode pattern structure 173a, the first capping layer pattern 174, and the second hard mask pattern 176 are stacked may be disposed on the N-type transistor region. The second gate electrode pattern structure 173a may include the second work function control layer pattern 170a and the third conductive layer pattern 172a.

The interface layer pattern 150a, the first gate insulation layer pattern 152a, the second gate electrode pattern structure 173a, the first capping layer pattern 174, and the second hard mask pattern 176 included in the N-type gate structure 184 and the interface layer pattern 150a, the first gate insulation layer pattern 152a, the second gate electrode pattern structure 173a, the first capping layer pattern 174, and the second hard mask pattern 176 included in the selection gate structure 180 and the P-type gate structure may be formed by same processes, respectively. The interface layer pattern 150a, the first gate insulation layer pattern 152a, the second gate electrode pattern structure 173a, the first capping layer pattern 174, and the second hard mask pattern 176 included in the N-type gate structure 184 may have materials the same as of materials of the interface layer pattern 150a, the first gate insulation layer pattern 152a, the second gate electrode pattern structure 173a, the first capping layer pattern 174, and the second hard mask pattern 176 included in the selection gate structure 180 and the P-type gate structure, respectively.

The N-type gate structure 184 may be formed on a surface of the first gate insulation layer pattern to have a second work function suitable for the N-type transistor. The N-type gate structure 184 may include the second work function control layer pattern 170a and the third conductive layer pattern 172a. Accordingly, the N-type transistor may have a target threshold voltage.

The second work function control layer pattern 170a and the third conductive layer pattern 172a included in the selection gate structure 180 and the P-type gate structure 182 may be formed together by processes for forming the N-type gate structure 184. The second work function control layer pattern 170a and the third conductive layer pattern 172a included in the selection gate structure 180 and the P-type gate structure 182 may not remove, and may remain on the first gate electrode pattern structure 160b. The second work function control layer pattern 170a and the third conductive layer pattern 172a included in the selection gate structure 180 and the P-type gate structure 182 may not affect threshold voltages of the selection gate transistor and the P-type transistor. Fifth spacers 190 may be formed on both sides of the selection gate structure 180, the P-type gate structure 182, and the N-type gate structure 184.

Second source/drain regions 192 may be disposed at the substrate 100 adjacent to both sidewalls of the selection gate structure 180, respectively. The second source/drain regions 192 may be doped with N-type impurities. The selection transistor may include the selection gate structure 180 and the second source/drain regions 192, and may be an N-type transistor.

Third source/drain regions 194 may be disposed at the substrate 100 adjacent to both sidewalls of the P-type gate structure 182, respectively. The third source/drain regions 194 may be doped with P-type impurities. The P-type transistor may include the P-type gate structure 182 and the third source/drain regions 194.

Fourth source/drain regions 196 may be disposed at the substrate 100 adjacent to both sidewalls of the N-type gate structure, respectively. The fourth source/drain regions 196 may be doped with N-type impurities. The N-type transistor may include the N-type gate structure 184 and the fourth source/drain regions 196.

As described above, the selection gate structure 180 included in the selection transistor and the P-type gate structure 182 included in the P-type transistor may include the same material, and have the same stacked structure. Damages of the first gate insulation layer pattern 152a included in the selection gate structure 180 may be decreased. Accordingly, a distribution of on-currents of the selection transistor and leakage currents of the selection transistor may be decreased.

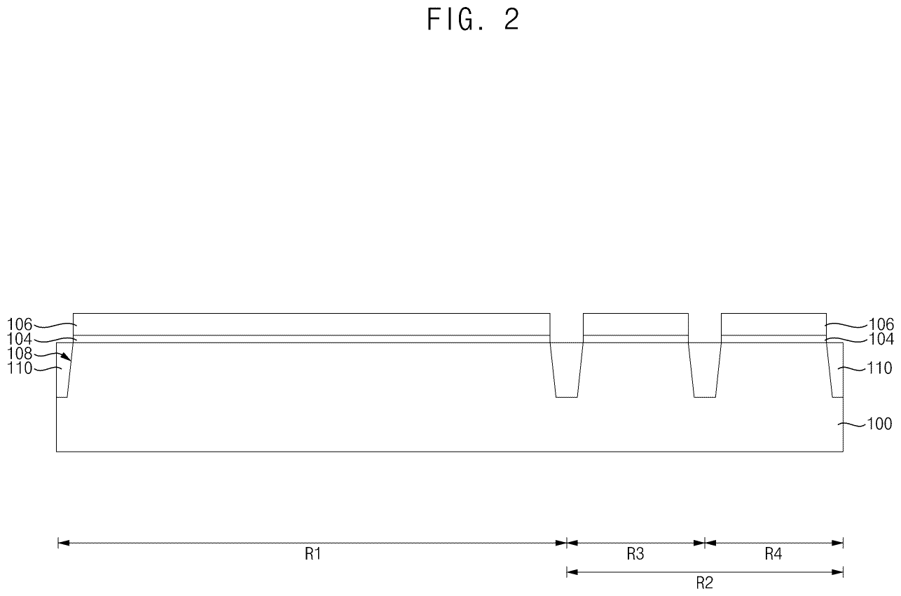

FIGS. 2 to 14 are cross-sectional views illustrating a method of manufacturing a semiconductor device according to example embodiments.

Referring to FIG. 2, a substrate 100 including a memory cell region R1 and a peripheral circuit region R2 may be provided. The memory cell region R1 may be a region where non-volatile memory cells are formed. The peripheral circuit region R2 may include an NMOS transistor region R3 and a PMOS transistor region R4.

A shallow trench isolation process may be performed on the substrate 100 to form isolation patterns 110. An upper surface of the substrate 100 between the isolation patterns 110 may serve as an active region, and the isolation pattern 110 may serve as a field region.

In example embodiments, a first mask layer and a second mask layer may be sequentially formed on the substrate 100, and the first mask layer and the second mask layer may be patterned to form the first mask pattern 104 and the second mask pattern 106. The first mask pattern 104 may include, e.g., silicon oxide, and the second mask pattern 106 may include, e.g., silicon nitride. A portion of the substrate 100 may be etched using a stacked structure of the first and second mask patterns 104 and 106 as an etch mask to form an isolation trench. Thereafter, an insulation material may fill the isolation trench, and a planarization process of the insulation material may be performed to form the isolation pattern 110. The planarization process may include a chemical mechanical polishing and/or an etch-back process.

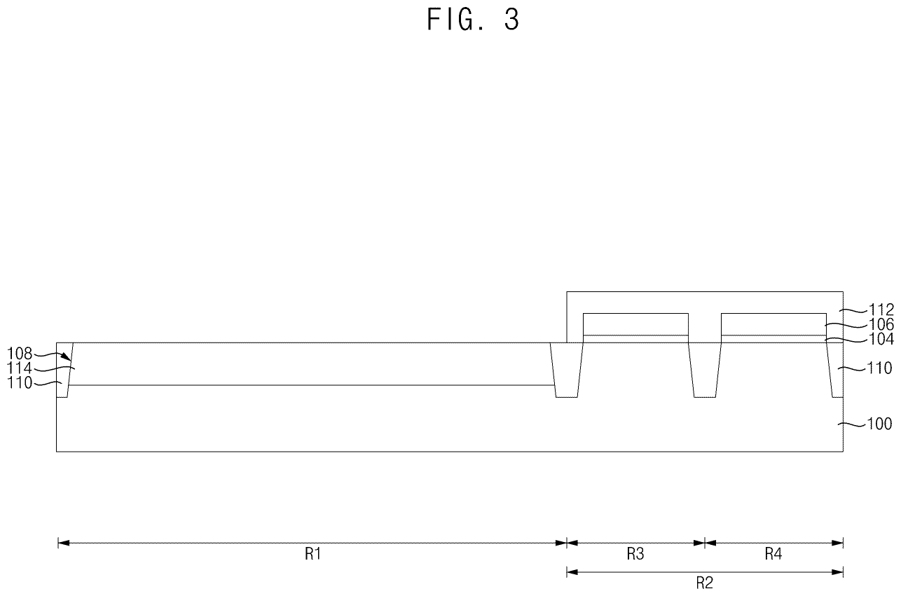

Referring to FIG. 3, a first protective layer pattern 112 may be formed to cover or overlap the first and second mask patterns 104 and 106 and the isolation pattern 110 on the peripheral circuit region R2. The first and second mask patterns 104 and 106 on the memory cell region R1 may be removed. Accordingly, an upper surface of the substrate 100 of the memory cell region R1 (i.e., an upper surface of the active region) may be exposed. The first protective layer pattern 112 and the first and second mask patterns 104 and 106 may remain on the peripheral circuit region R2 of the substrate 100. In some example embodiments, the first protective layer pattern 112 may be removed, and only the first and second mask patterns 104 and 106 may remain on the peripheral circuit region R2 of the substrate 100. In some example embodiments, the first and second mask patterns 104 and 106 may be removed, and only the first protective layer pattern 112 may remain on the peripheral circuit region R2 of the substrate 100.

Impurities may be doped on the memory cell region R1 of the substrate 100 to form a well region 114. In example embodiments, the well region 114 may be doped with P-type impurities.

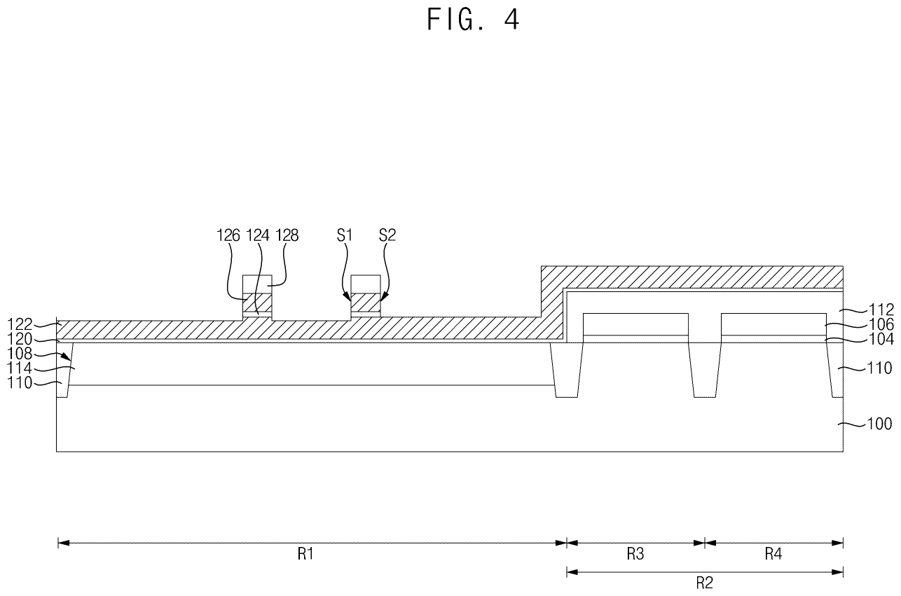

Referring to FIG. 4, a tunnel insulation layer 120 and a floating gate layer 122 may be sequentially formed on the memory cell region R1 of the substrate 100. In example embodiments, the tunnel insulation layer 120 may include silicon oxide, and the floating gate layer 122 may include polysilicon.

A first dielectric layer may be formed on the floating gate layer 122. A control gate layer may be formed on the first dielectric layer. In example embodiments, the first dielectric layer may include silicon nitride or silicon oxide, and the control gate layer may include polysilicon.

A first hard mask pattern 128 may be formed on the control gate layer. In example embodiments, the first hard mask pattern 128 may include silicon nitride.

The first hard mask pattern 128 may be used as an etch mask to form the cell gate structure 138 of the cell transistor in subsequent processes. Therefore, the first hard mask pattern 128 may cover or overlap a region for forming the cell gate structure 138. The first hard mask pattern 128 may not be formed on the peripheral circuit region R2.

The control gate layer and the first dielectric layer may be sequentially etched using the first hard mask pattern 128 as the etch mask to form a control gate pattern 126 and a first dielectric layer pattern 124. The control gate layer and the first dielectric layer on the peripheral circuit region R2 may be entirely removed by the etching process. After the etching process, an upper portion of the floating gate layer 122 may be exposed. In example embodiments, the upper portion of the floating gate layer 122 may be partially removed by the etching process. In some example embodiments, the floating gate layer 122 may not be removed by the etching process.

An upper structure in which the first dielectric layer pattern 124, the control gate pattern 126, and the first hard mask pattern 128 are stacked may be formed on the floating gate layer 122. Two upper structures may be disposed to face each other.

Through subsequent process, a cell gate structure 138 (refer to FIG. 1) including the upper structure may be formed. In two opposing cell gate structures 138, facing sidewalls of the cell gate structures 138 are referred to as first sidewalls S1, and sidewalls opposite to each of the first sidewalls S1 are referred to as second sidewall S2.

Through subsequent processes, a common erase transistor may be formed between two cell gate structures 138 facing each other. An erase transistor may be formed between the first sidewalls S1 of the cell gate structures 138. A selection transistor may be formed outside the second sidewall S2 of the cell gate structure 138.

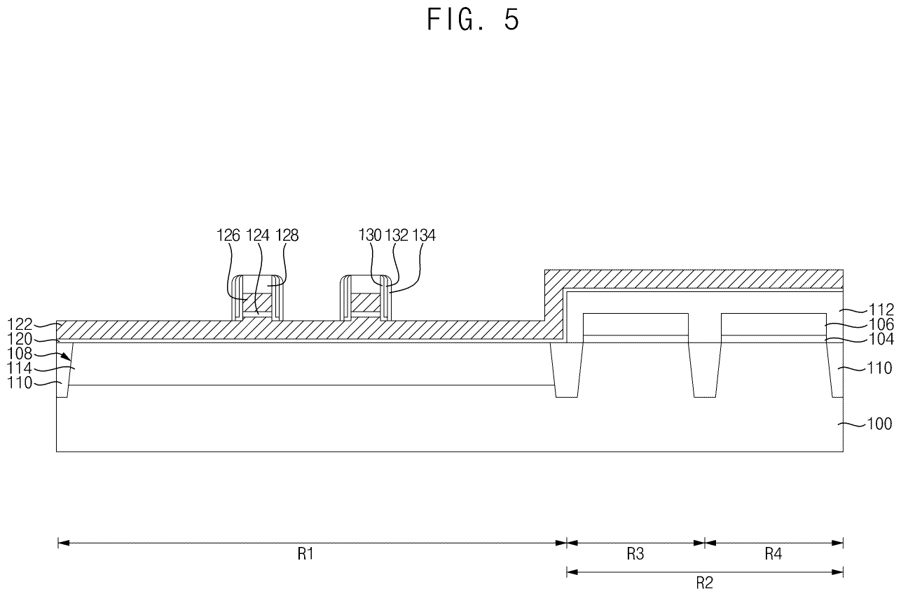

Referring to FIG. 5, a first spacer 130, a second spacer 132 and a third spacer 134 may be sequentially formed on each of sidewalls of the upper structure in which the first dielectric layer pattern 124, the control gate pattern 126, and the first hard mask pattern 128 are stacked.

Particularly, a first spacer layer may be formed along the upper structure in which the first dielectric layer pattern 124, the control gate pattern 126, and the first hard mask pattern 128 are stacked, and a surface of the floating gate layer 122. A second spacer layer and a third spacer layer may be sequentially formed on the first spacer layer. In example embodiments, the first spacer layer and the third spacer layer may include silicon oxide, and the second spacer layer may include silicon nitride. Thereafter, the third spacer layer, the second spacer layer, and the first spacer layer may be sequentially anisotropically etched to form the first, second, third, and third spacers 130, 132, and 134.

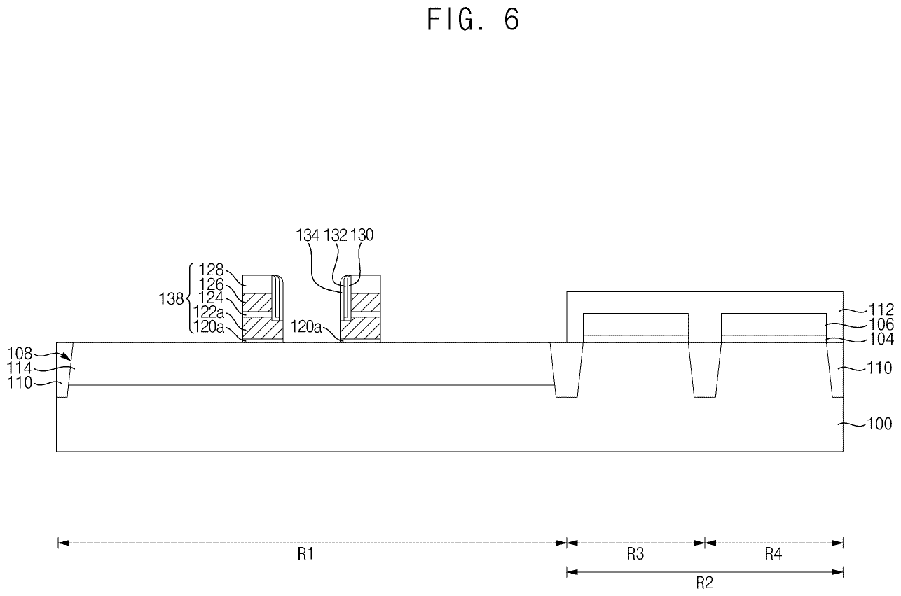

Referring to FIG. 6, the first, second, third, and third spacers 130, 132, and 134 on the second sidewall of the upper structure in which the first dielectric layer pattern 124, the control gate pattern 126, and the first hard mask pattern 128 are stacked may be selectively removed. Accordingly, the first, second, third, and third spacers 130, 132, 134 may be formed only on the first sidewall S1 of the upper structure in which the first dielectric layer pattern 124, the control gate pattern 126, and the first hard mask pattern 128 are stacked.

The floating gate layer and the tunnel insulation layer may be etched using the first hard mask pattern 128, the first spacer 130, second spacer 132, and third spacer 134 as an etch mask to form a floating gate pattern 122a and a tunnel insulation layer pattern 120a. The floating gate pattern 122a may have a width greater than a width of the control gate pattern 126. A sidewall of the floating gate pattern 122a may protrude from the first sidewall of the control gate pattern 126 toward a region of the erase transistor.

Through the above processes, the cell gate structure 138 in which the tunnel insulation layer pattern 120a, the floating gate pattern 122a, the first dielectric layer pattern 124, and the first hard mask pattern 128 are stacked may be formed.

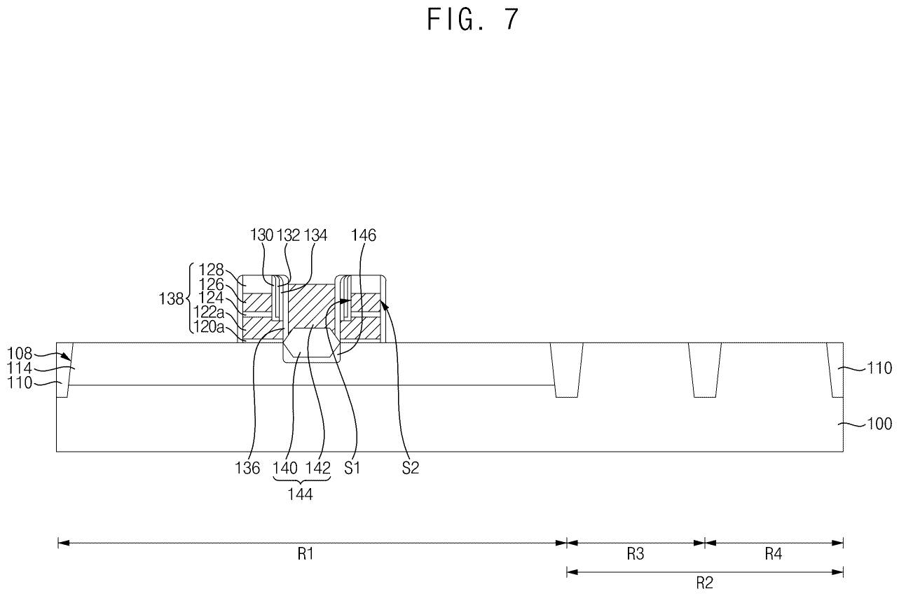

Referring to FIG. 7, a fourth spacer layer may be formed on surfaces of the first, second, third, and third spacers 130, 132, and 134, the first hard mask pattern 128, the control gate pattern 126, the first dielectric layer pattern 124, the floating gate pattern 122a, the tunnel insulation layer pattern 120a, the substrate 100 and the first protective layer pattern 112. The fourth spacer layer may be anisotropically etched to form a fourth spacer 136 on sidewalls of the third spacer 134, the first hard mask pattern 128, the control gate pattern 126, the first dielectric layer pattern 124, the floating gate pattern 122a and the tunnel insulation layer pattern 120a.

In example embodiments, impurities may be doped onto an exposed upper portion of the substrate 100 in the erase transistor region to form a first source/drain region 146.

An erase gate insulation layer 140 may be selectively formed on an exposed upper surface of the substrate 100 in the erase transistor region. In example embodiments, the erase gate insulation layer 140 may include silicon oxide. In example embodiments, the erase gate insulation layer 140 may be formed by oxidizing of the substrate 100 including silicon.

An erase gate electrode layer may be formed on the erase gate insulation layer 140 and the substrate 100. Thereafter, the erase gate electrode layer on remaining regions excluding the erase transistor region may be removed to form an erase gate pattern 142.

The erase gate pattern 142 may be formed inside a space between the cell gate structures 138 facing each other. The erase gate pattern 142 may be formed on the erase gate insulation layer 140 to fill at least a portion of the space between the cell gate structures 138. An uppermost surface of the erase gate pattern 142 may be lower than an uppermost surface of the cell gate structure 138.

Thereafter, the first protective layer pattern 112 and the first and second mask patterns 104 and 106 on the peripheral circuit region R2 of the substrate 100 may be removed.

An erase gate structure 144 in which the erase gate insulation layer 140 and the erase gate pattern 142 are stacked may be formed by performing the above process. The surface of the substrate 100 in the selection transistor region located outside the second sidewall S2 of the cell gate structure 138 may be exposed. Additionally, the surface of the substrate 100 in the peripheral circuit region R2 may be exposed.

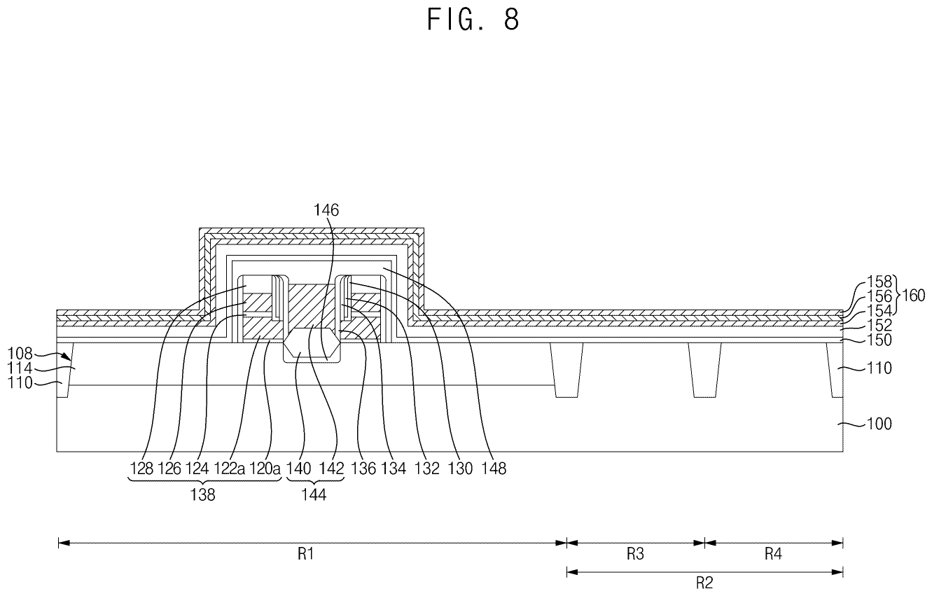

Referring to FIG. 8, a second protective layer pattern 148 may be formed to cover or overlap the cell gate structures 138 and the erase gate structure 144 between the cell gate structures 138.

An interface layer 150 may be formed on surfaces of the substrate 100, the isolation pattern 110, and the second protective layer pattern 148. The interface layer 150 may include, e.g., silicon oxide. The interface layer 150 on the substrate 100 may be formed by oxidizing the substrate 100.

A first gate insulation layer 152 may be formed on the interface layer 150. The first gate insulation layer 152 may serve as gate insulation layers of the selection transistor in the memory cell region R1, and for the N-type transistor and the P-type transistor in the peripheral circuit region R2.

The first gate insulation layer 152 may include metal oxide having a dielectric constant higher than a dielectric constant of silicon nitride. In example embodiments, the first gate insulation layer 152 may include hafnium oxide, zirconium oxide, aluminum oxide, or the like. For example, the first gate insulation layer 152 may include hafnium oxide.

A preliminary first gate electrode layer structure 160 may be formed on the first gate insulation layer 152. The preliminary first gate electrode layer structure 160 may include a suitable material for forming the P-type transistor having target characteristics. The preliminary first gate electrode layer structure 160 may have a work function suitable for the P-type transistor. The preliminary first gate electrode layer structure 160 may include a metal.

In example embodiments, the preliminary first gate electrode layer structure 160 may have a sandwich structure in which a first conductive layer 154, a first work function control layer 156, and a second conductive layer 158 are sequentially stacked. For example, the first and second conductive layers 154 and 158 may include the same material. The first and second conductive layers 154 and 158 may include, e.g., TiN, TiC, Co, TiAlC, TiAl, TaN, TaAlC, etc. The first work function control layer 156 may include a chemical species for controlling a threshold voltage of the P-type transistor. The first work function control layer 156 may include, e.g., aluminum.

For example, the preliminary first gate electrode layer structure 160 may have a structure in which a titanium nitride layer, an aluminum layer, and a titanium nitride layer are sequentially stacked.

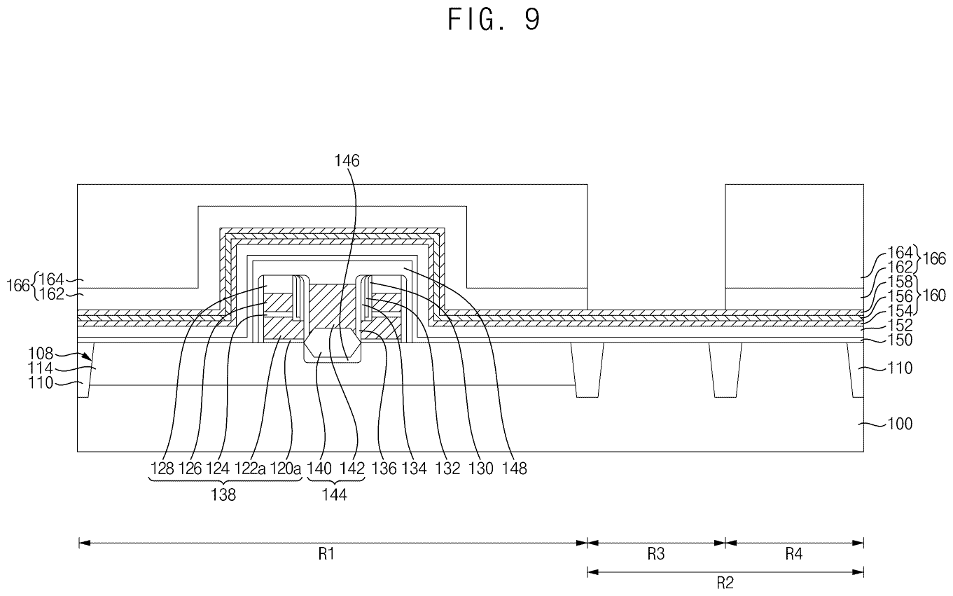

Referring to FIG. 9, a lower anti-reflection layer and a third mask pattern 164 may be formed on the preliminary first gate electrode layer structure 160. The lower anti-reflection layer may include, e.g., SiON or a polymer material. The third mask pattern 164 may be, e.g., a photoresist pattern.

The third mask pattern 164 may selectively cover or overlap the P-type transistor region R4 in the peripheral circuit region R2 and the memory cell region R1. The lower anti-reflective layer may be etched using the third mask pattern 164 as an etch mask to form a lower anti-reflective pattern 162. A structure in which the lower anti-reflection pattern 162 and the third mask pattern 164 are stacked is referred to as a first mask pattern structure 166.

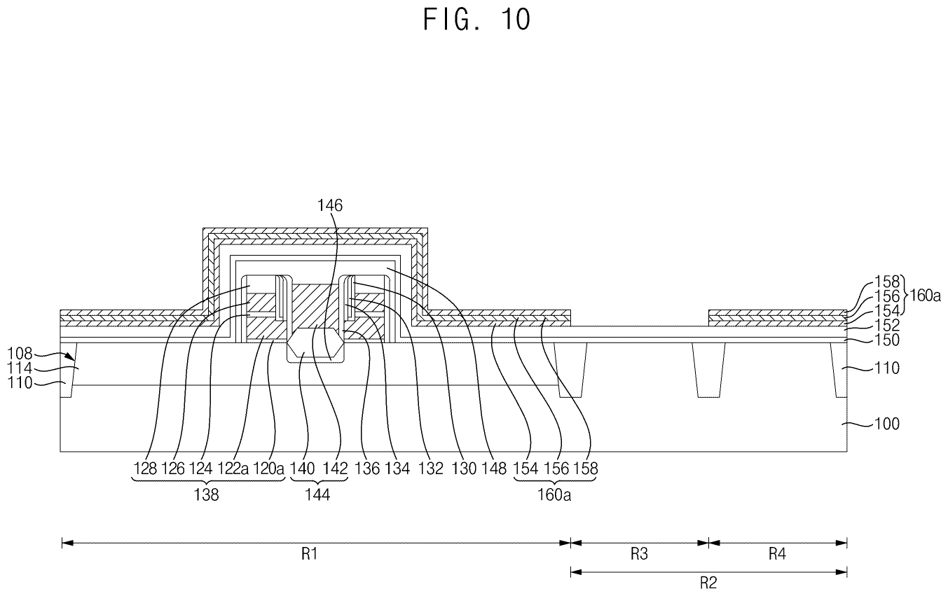

Referring to FIG. 10, the preliminary first gate electrode layer structure 160 may be etched using the first mask pattern structure 166 as an etch mask to expose the first gate insulation layer 152. Thus, first gate electrode layer structures 160a may be formed on the memory cell region R1 and the P-type transistor region R4.

In the etching process, the preliminary first gate electrode layer structure 160 formed on the N-type transistor region R3 may be removed, so that the first gate insulation layer 152 on the N-type transistor region R3 may be exposed.

As described above, the preliminary first gate electrode layer structure 160 on the memory cell region R1 may not be removed by the etching process, so that the first gate insulation layer 152 on the memory cell region R1 may not be damaged in the etching process. Accordingly, defects (e.g., increasing of leakage currents and on-current distribution, etc.) due to damages of the first gate insulation layer 152 on the memory cell region R1 may be decreased. Additionally, first gate electrode layer structures 160a on the memory cell region R1 and the P-type transistor region R4 may be formed together by the etching process. Therefore, the first gate electrode layer structures 160a may be formed by a simple process.

Thereafter, the first mask pattern structure 166 may be removed. Accordingly, the upper surface of the first gate electrode layer structure 160a on the P-type transistor region R4 and the memory cell region R1 may be exposed. The removing process may include, e.g., an ashing process and/or a stripping process.

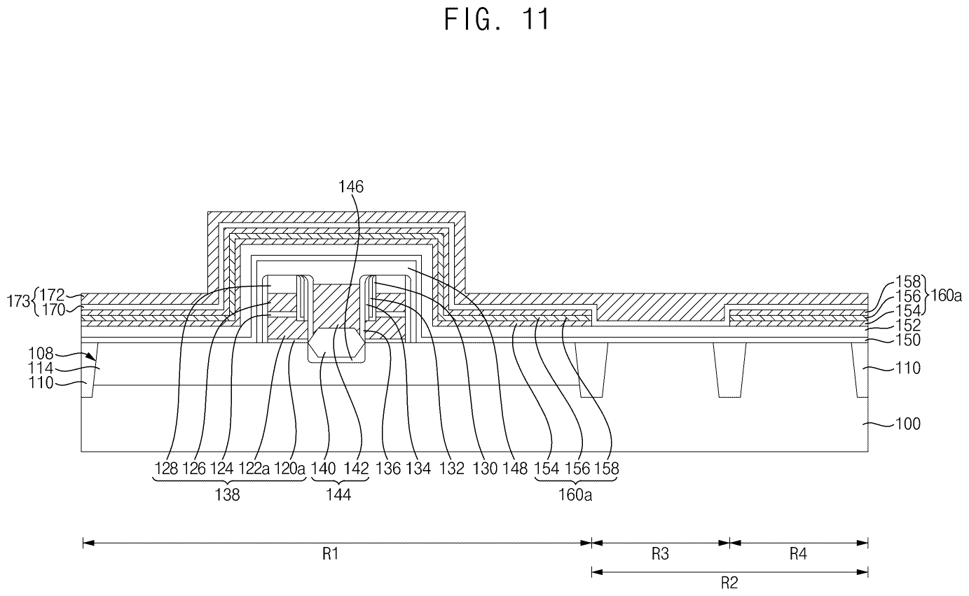

Referring to FIG. 11, a second gate electrode layer structure 173 may be formed on the first gate electrode layer structure 160a and the first gate insulation layer 152. The second gate electrode layer structure 173 may include a suitable material for forming the N-type transistor having target characteristics. The second gate electrode layer structure 163 may have a work function suitable for the N-type transistor. The second gate electrode layer structure 173 may include a metal.

In example embodiments, the second gate electrode layer structure 173 may have a structure in which a second work function control layer 170 and a third conductive layer 172 are stacked.

The second work function control layer 170 may include chemical species for controlling the threshold voltage of the N-type transistor. The chemical species may include lanthanide elements. The second work function control layer 170 may include, e.g., lanthanum oxide (LaO).

The third conductive layer 172 may include a metal. The third conductive layer 172 may include, e.g., TiN, TaN, TaAlC, TiC, Co, TiAl, HfTi, TiSi, TaSi, etc. For example, the third conductive layer 172 may include titanium nitride.

The interface layer 150, the first gate insulation layer 152, the first gate electrode layer structure 160a and the second gate electrode layer structure 173 may be stacked on the P-type transistor region R4 and the memory cell region R1 of the substrate 100. For example, the interface layer 150, the first gate insulation layer 152, the first conductive layer 154, and the first work function control layer 156, the second conductive layer 158, the second work function control layer 170 and the third conductive layer 172 may be stacked on the P-type transistor region R4 and the memory cell region R1 of the substrate 100.

The interface layer 150, the first gate insulation layer 152 and the second gate electrode layer structure 173 may be stacked on the N-type transistor region R3 of the substrate 100. For example, the interface layer 150, the first gate insulation layer 152, the second work function control layer 170 and the third conductive layer 172 may be stacked on the N-type transistor region R3 of the substrate 100.

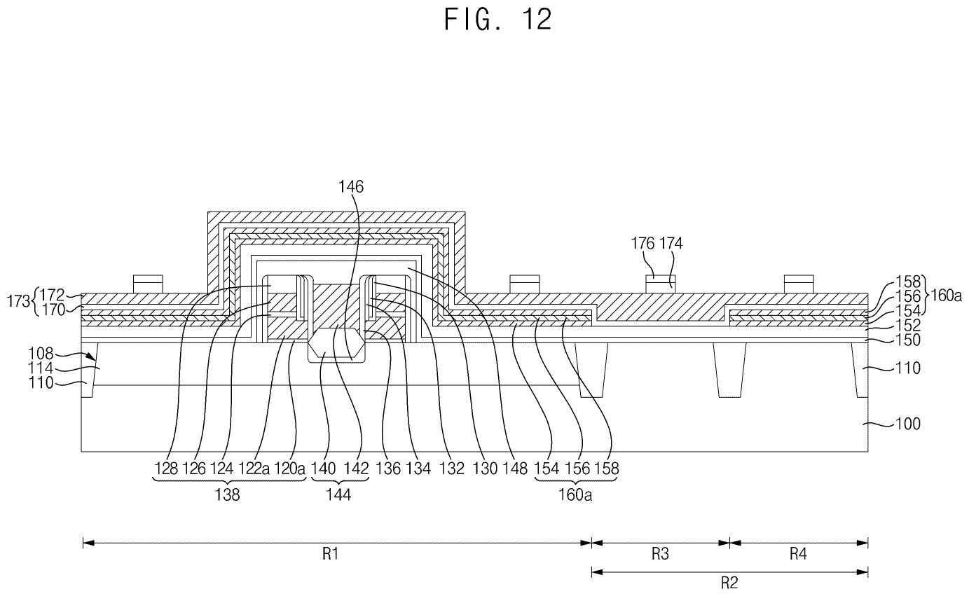

Referring to FIG. 12, a first capping layer may be formed on the third conductive layer 172. The first capping layer may include, e.g., polysilicon.

A second hard mask pattern 176 may be formed on the first capping layer. The second hard mask pattern 176 may include, e.g., silicon nitride or silicon oxynitride. The second hard mask pattern 176 may serve as an etch mask for forming gate structures of the selection transistor, the P-type transistor, and the N-type transistor. Accordingly, the second hard mask pattern 176 may cover or overlap regions corresponding to the gate structures of the selection transistor, the P-type transistor, and the N-type transistor.

The first capping layer may be etched using the second hard mask pattern 176 as an etch mask to form the first capping layer pattern 174.

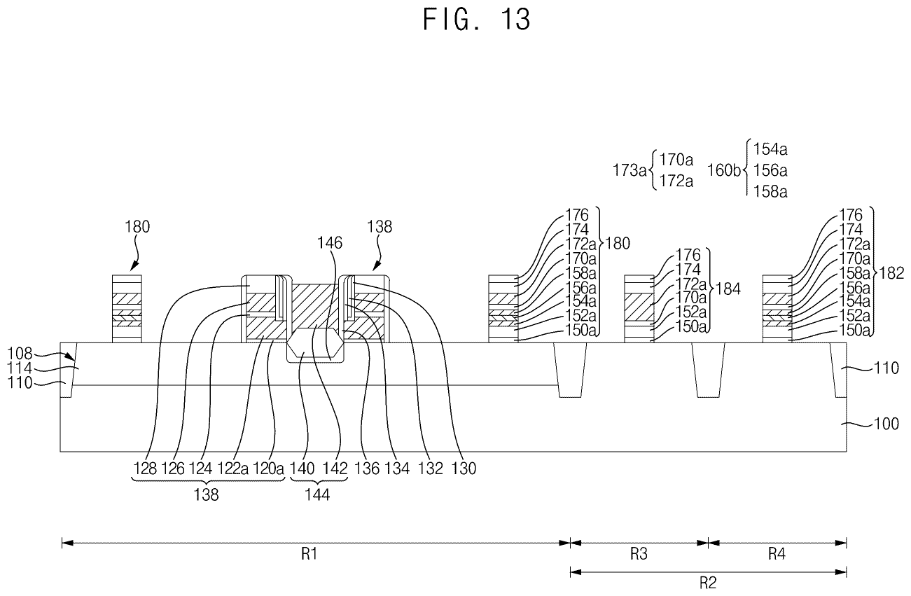

Referring to FIG. 13, the second gate electrode layer structure 173 and the first gate electrode layer structures 160a, the first gate insulation layer 152 and the interface layer 150 may be sequentially etched by using the second hard mask pattern 176 and the first capping layer pattern 174 as an etch mask, so that a selection gate structure 180 of the selection transistor, a P-type gate structure 182 of the P-type transistor and an N-type gate structure 184 of the N-type transistor may be formed.

The selection gate structure 180 and the P-type gate structure 182 may have the same stacked structure. Each of the selection gate structure 180 and the P-type gate structure 182 may have a stacked structure in which an interface layer pattern 150a, a first gate insulation layer pattern 152a, a first gate electrode pattern structure 160b, a second gate electrode pattern structure 173a, the first capping layer pattern 174 and the second hard mask pattern 176 are stacked. The first gate electrode pattern structure 160b may include the first conductive layer pattern 154a, the first work function control layer pattern 156a and the second conductive layer pattern 158a, and the second gate electrode pattern structure 173a may include the second work function control layer pattern 170a and the third conductive layer pattern 172a.

In the selection gate structure 180 and the P-type gate structure 182, the first gate electrode pattern structure 160b, which is a P gate electrode structure suitable for a P-type transistor, may be disposed on the first gate insulation layer pattern 152a.

The N-type gate structure 184 may have a stacked structure in which the interface layer pattern 150a, the first gate insulation layer pattern 152a and the second gate electrode pattern structure 173a are stacked. The second gate electrode pattern structure 173a may include the second work function control layer pattern 170a and the third conductive layer pattern 172a.

In the N-type gate structure 184, the second gate electrode pattern structure 173a, which is an N gate electrode structure suitable for the N-type transistor, may be disposed on the first gate insulation layer pattern 152a.

The second protective layer pattern 148 may be removed.

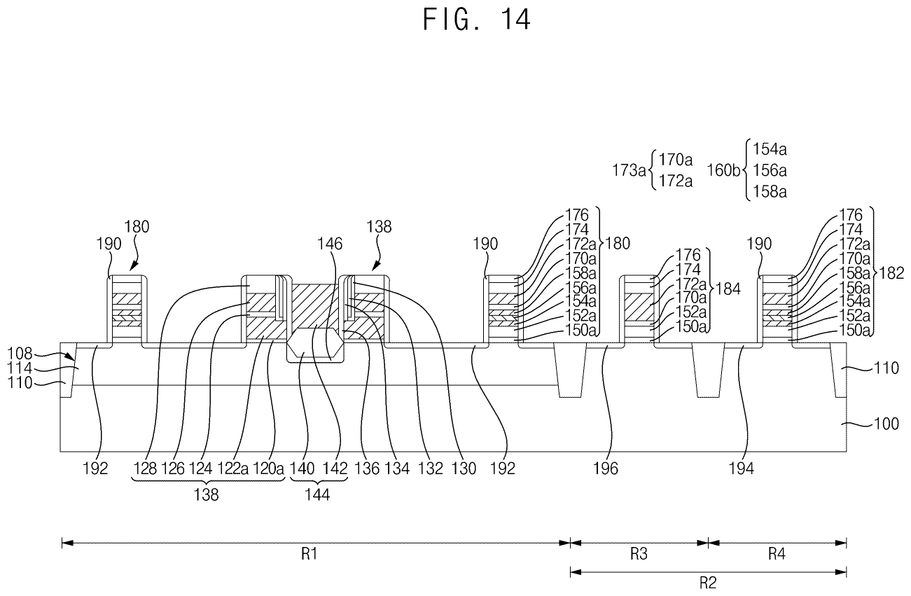

Referring to FIG. 14, fifth spacers 190 may be formed on both sides of the selection gate structure 180, the P-type gate structure 182, and the N-type gate structure 184.

Second source/drain regions 192 may be formed at the substrate 100 adjacent to both sides of the selection gate structure 180. The second source/drain regions 192 may be doped with N-type impurities. Accordingly, a selection transistor including the selection gate structure 180 and the second source/drain regions 192 may be formed. The selection transistor may be the N-type transistor.

Third source/drain regions 194 may be formed at the substrate 100 adjacent to both sides of the P-type gate structure 182. The third source/drain regions 194 may be doped with P-type impurities.

Fourth source/drain regions 196 may be formed at the substrate 100 adjacent to both sides of the N-type gate structure 184. The fourth source/drain regions 196 may be doped with N-type impurities.

By performing the above processes, a semiconductor device including the cell transistor, the selection transistor, and the erase transistor on the memory cell region R1, and the N-type transistor and the P-type transistor on the peripheral circuit region R2 may be manufactured. The selection transistor and the P-type transistor may have different conductivity types. The selection gate structure 180 of the selection transistor and the P-type gate structure 182 of the P-type transistor may have the same stacked structure.

According to the above process, the semiconductor device may be formed by simple processes. A distribution of processes for manufacturing the semiconductor device may be decreased, and a distribution of on-currents of the semiconductor device may be decreased. Additionally, leakage currents in the semiconductor device may be decreased.

While the present inventive concepts have been shown and described with reference to example embodiments thereof, it will be understood by those of ordinary skill in the art that various changes in form and details may be made thereto without departing from the scope of the present inventive concepts as set forth by the following claims.

What is claimed is:

1. A semiconductor device, comprising:
a first cell gate structure and a second cell gate structure on a cell region of a substrate;
an erase gate structure on the substrate, wherein the erase gate structure is between respective first sidewalls of the first cell gate structure and the second cell gate structure;
selection gate structures on the substrate that are spaced apart from respective second sidewalls opposing the respective first sidewalls of each of the first cell gate structure and the second cell gate structure, wherein each of the selection gate structures includes a first gate insulation layer pattern including a first metal oxide and a first gate electrode pattern structure on the first gate insulation layer pattern;
a P-type gate structure on a peripheral circuit region of the substrate, the P-type gate structure including the first gate insulation layer pattern that includes the first metal oxide and the first gate electrode pattern structure on the first gate insulation layer pattern; and
an N-type gate structure on the peripheral circuit region of the substrate, the N-type gate structure including the first gate insulation layer pattern that includes the first metal oxide and a second gate electrode pattern structure on the first gate insulation layer pattern, wherein the second gate electrode pattern structure has a stacked structure different from a stacked structure of the first gate electrode pattern structure.

2. The semiconductor device of claim 1, wherein the first metal oxide includes at least of hafnium oxide, zirconium oxide, or aluminum oxide.

3. The semiconductor device of claim 1, further comprising:
an interface layer pattern between the first gate insulation layer pattern included in each of the selection gate structures, the P-type gate structure, and the N-type gate structure and a surface of the substrate.

4. The semiconductor device of claim 1, wherein the first gate electrode pattern structure includes a first conductive layer pattern, a first work function control layer pattern, and a second conductive layer pattern.

5. The semiconductor device of claim 4, wherein the first and second conductive layer patterns include TiN, TiC, Co, TiAlC, TiAl, TaN, or TaAlC, and the first work function control layer pattern includes aluminum.

6. The semiconductor device of claim 1, wherein the second gate electrode pattern structure includes a second work function control layer pattern and a third conductive layer pattern.

7. The semiconductor device of claim 6, wherein the second work function control layer pattern includes LaO, and the third conductive layer pattern includes TiN, TaN, TaAlC, TiC, Co, TiAl, HfTi, TiSi, or TaSi.

8. The semiconductor device of claim 1, wherein each of the first cell gate structure and the second cell gate structure comprises a tunnel insulation layer pattern, a floating gate pattern, a first dielectric layer pattern, a control gate pattern, and a first hard mask pattern that are on one another.

9. The semiconductor device of claim 1, wherein the erase gate structure comprises an erase gate electrode on an erase gate insulation layer.

10. The semiconductor device of claim 1, wherein the second gate electrode pattern structure is on an upper surface of the first gate electrode pattern structure that is included in the selection gate structures and the P-type gate structure.

11. The semiconductor device of claim 1, further comprising:
first source/drain regions doped with N-type impurities in the substrate adjacent to sidewalls of the selection gate structures;
second source/drain regions doped with P-type impurities in the substrate adjacent to sidewalls of the P-type gate structure; and
third source/drain regions doped with N-type impurities in the substrate adjacent to sidewalls of the N-type gate structure.

12. A semiconductor device, comprising:
a first cell transistor and a second cell transistor on a cell region of a substrate;
an erase transistor between the first cell transistor and the second cell transistor;
selection transistors on the substrate that are each spaced apart from both the first cell transistor and the second cell transistor, wherein each of the selection transistors comprises a selection gate structure including an interface layer, a first gate insulation layer pattern including a first metal oxide having a dielectric constant higher than a dielectric constant of silicon nitride, and a first gate electrode pattern structure on the first gate insulation layer pattern and having a first stacked structure;
a P-type transistor on a peripheral circuit region of the substrate, wherein the P-type transistor comprises a P-type gate structure having the interface layer, the first gate insulation layer pattern including the first metal oxide, and the first gate electrode pattern structure on the first gate insulation layer pattern and having the first stacked structure; and
an N-type transistor on the peripheral circuit region of the substrate, wherein the N-type transistor comprises an N-type gate structure having the interface layer, the first gate insulation layer pattern including the first metal oxide, and a second gate electrode pattern structure on the first gate insulation layer pattern and having a second stacked structure different from the first stacked structure.

13. The semiconductor device of claim 12, wherein the first gate electrode pattern structure includes a first conductive layer pattern, a first work function control layer pattern, and a second conductive layer pattern.

14. The semiconductor device of claim 13, wherein the first and second conductive layer patterns include TiN, TiC, Co, TiAlC, TiAl, TaN, or TaAlC, and the first work function control layer pattern includes aluminum.

15. The semiconductor device of claim 12, wherein the second gate electrode pattern structure includes a second work function control layer pattern and a third conductive layer pattern.

16. The semiconductor device of claim 15, wherein the second work function control layer pattern includes LaO, and the third conductive layer pattern includes TiN, TaN, TaAlC, TiC, Co, TiAl, HfTi, TiSi, or TaSi.

17. The semiconductor device of claim 15, wherein the second gate electrode pattern structure is on an upper surface of the first gate electrode pattern structure included in the selection gate structure of each of the selection transistors and the P-type gate structure of the P-type transistor.

18. A semiconductor device, comprising:
a selection gate structure on a cell region of a substrate, the selection gate structure including a first gate electrode pattern structure and a second gate electrode pattern structure on the first gate electrode pattern structure, wherein the first gate electrode pattern structure includes an interface layer, a first gate insulation layer pattern including a first metal oxide, a first conductive layer pattern on the first gate insulation layer pattern, a first work function control layer pattern and a second conductive layer pattern, and wherein the second gate electrode pattern structure includes a second work function control layer pattern and a third conductive layer pattern;
a P-type gate structure on a peripheral circuit region of the substrate, the P-type gate structure including the first gate electrode pattern structure and the second gate electrode pattern structure on the first gate electrode pattern structure;
an N-type gate structure on the peripheral circuit region of the substrate, the N-type gate structure including the interface layer, the first gate insulation layer pattern including the first metal oxide, and the second gate electrode pattern structure on the first gate insulation layer pattern;
first source/drain regions doped with N-type impurities in the substrate adjacent to sidewalls of the selection gate structure;
second source/drain regions doped with P-type impurities in the substrate adjacent to sidewalls of the P-type gate structure; and
third source/drain regions doped with N-type impurities in the substrate adjacent to sidewalls of the N-type gate structure.

19. The semiconductor device of claim 18, wherein the first and second conductive layer patterns each include TiN, TiC, Co, TiAlC, TiAl, TaN, or TaAlC, and the first work function control layer pattern includes aluminum.

20. The semiconductor device of claim 18, wherein the second work function control layer pattern includes LaO, and the third conductive layer pattern includes TiN, TaN, TaAlC, TiC, Co, TiAl, HfTi, TiSi, or TaSi.
